(19) United States
(12) Patent Application Publication
(10) Pub. No.: US 2026/0129973 A1
(43) Pub. Date: May 7, 2026

(54) HYBRID DRIVE ELECTRONIC DEVICE FOR ENHANCING DISPLAY PERFORMANCE OF LOW-GRAYSCALE PIXELS

(71) Applicant: InnoLux Corporation, Miao-Li County (TW)

(72) Inventors: Jia-Yuan CHEN, Miaoli County (TW); Sheng-Feng Huang, Miao-Li County (TW); Tsung-Han Tsai, Miao-Li County (TW); Kuan-Feng Lee, Miao-Li County (TW)

(73) Assignee: InnoLux Corporation, Miao-Li County (TW)

(21) Appl. No.: 19/337,943

(22) Filed: Sep. 24, 2025

(30) Foreign Application Priority Data
Nov. 4, 2024 (CN) 202411556253.7

(51) Int. Cl. H10D 86/60; G09G 3/20; G09G 3/32; H10D 86/40; H10H 29/32

(52) U.S. Cl. CPC H10D 86/60; G09G 3/2011; G09G 3/2081; G09G 3/32; H10D 86/423; H10D 86/441; H10H 29/32; G09G 2300/0465; G09G 2300/0852; G09G 2300/0861; G09G 2310/0297; G09G 2310/08; G09G 2320/0276; G09G 2330/12

(57) ABSTRACT

An electronic device includes an electronic unit, an integrated circuit, a first transistor and a second transistor. The integrated circuit is used to provide a sweep signal. The first transistor includes a first semiconductor, a first terminal electrically connected to a power source, a second terminal electrically connected to the electronic unit, and a first control terminal. The second transistor includes a second semiconductor, a third terminal configured to receive the sweep signal, a fourth terminal electrically connected to the first control terminal of the first transistor, and a second control terminal configured to receive a switch signal. The first transistor has a first channel width-to-length ratio, the second transistor has a second channel width-to-length ratio, of the first channel width-to-length ratio to the second channel width-to-length ratio is greater than or equal to 0.03 and less than or equal to 80.5.

### BACKGROUND OF THE DISCLOSURE

### 1. Field of the Disclosure

The disclosure is related to an electronic device, and more particularly to a hybrid drive electronic device.

### 2. Description of the Prior Art

In the prior art, multiple transistors were used to hybridly drive electronic devices, enabling the adjustment of various parameters and achieving diverse functionalities. For example, certain transistors were used to regulate voltage oscillation, while others controlled current frequency. However, if each group of pixels requires a pulse width modulation (PWM) transistor circuit and a pulse amplitude modulation (PAM) transistor circuit, the resulting large number of transistors can occupy significant space, limiting improvements in resolution. Therefore, reducing the number of transistors to save space has become a critical challenge.

### SUMMARY OF THE DISCLOSURE

An embodiment discloses an electronic device comprising an electronic unit, an integrated circuit, a first transistor and a second transistor. The integrated circuit is configured to provide a sweep signal. The first transistor includes a first semiconductor, a first terminal, a second terminal and a first control terminal. The first terminal is electrically connected to a power source, and the second terminal is electrically connected to the electronic unit. The second transistor includes a second semiconductor, a third terminal, a fourth terminal and a second control terminal. The third terminal is configured to receive the sweep signal, the fourth terminal is electrically connected to the first control terminal of the first transistor, and the second control terminal is configured to receive a switch signal. The first transistor has a first channel width-to-length ratio, the second transistor has a second channel width-to-length ratio, and a ratio of the first channel width-to-length ratio to the second channel width-to-length ratio is greater than or equal to 0.03 and less than or equal to 80.5.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of a circuit of an electronic device according to an embodiment of the disclosure.

FIG. 2A is a schematic diagram of an electronic device according to another embodiment of the disclosure.

FIG. 2B is a schematic diagram of an electronic device according to another embodiment of the disclosure.

FIG. 2C is a schematic diagram of a circuit of an electronic device according to another embodiment of the disclosure.

FIG. 3A is a cross-sectional view of the electronic device of FIG. 1.

FIG. 3B is a top view of a transistor in FIG. 3A.

FIG. 3C is a schematic diagram of the driving transistor in FIG. 3A.

FIG. 4 is a top view of a transistor according to another embodiment of the disclosure.

FIG. 5A is a top view of a driving transistor according to another embodiment of the disclosure.

FIG. 5B is a schematic diagram of the current curve of the driving transistor in FIG. 5A.

FIG. 6 is a cross-sectional view of an electronic device according to another embodiment of the disclosure.

FIG. 7A is a schematic diagram of a circuit of an electronic device according to another embodiment of the disclosure.

FIG. 7B is a cross-sectional view of an embodiment of the electronic device according to FIG. 7A.

FIG. 7C is a cross-sectional view of another embodiment of the electronic device according to FIG. 7A.

FIG. 8A is a schematic diagram of a circuit of an electronic device according to another embodiment of the disclosure.

FIG. 8B is a schematic diagram of an electronic device according to another embodiment of the disclosure.

FIG. 9 is a cross-sectional view of the electronic device of FIG. 8B.

FIG. 10 is a schematic diagram of an electronic device according to another embodiment of the disclosure.

FIG. 11 is a waveform diagram of a circuit of an electronic device according to an embodiment of the disclosure.

FIG. 12 is a schematic diagram of a circuit of an electronic device according to another embodiment of the disclosure.

### DETAILED DESCRIPTION

The structure, number of components, number of layers, positional arrangement, proportions, and other attributes of the icons described herein are provided solely as illustrative examples to facilitate understanding of the embodiments and should not be construed as limiting the style or scope of the embodiments. Furthermore, any ordinal terms such as ‘first,’ ‘second,’ etc., are used solely for distinguishing between different components and do not imply any specific sequence, order, or significance in the manufacturing process.

Certain terms are used throughout the description and claims of the present disclosure to refer to specific components. It should be understood by those skilled in the art that different manufacturers of electronic devices may refer to the same or similar components by different names. Accordingly, the terminology used herein is not intended to differentiate between components that perform the same function but are referred to by different terms. Furthermore, in the following description and claims, the terms ‘have’ and ‘include’ are intended to be open-ended expressions and should be interpreted as meaning ‘including, but not limited to.

It should be understood that when an element or layer is described as being “disposed on” or “connected to” another element or layer, it may be directly on or directly connected to another element or layer, or there may be one or more intervening elements or layers (non-direct contact) between them. Conversely, when an element is described as being ‘directly on’ or ‘directly connected to’ another element or layer, there are no intervening elements or layers present. The term ‘electrical connection’ or ‘electrical coupling’ as used in this disclosure may refer to either a direct connection or an indirect connection. In the case of a direct electrical connection, the endpoints of the components in the two circuits are directly connected or joined via a conductor segment. In the case of an indirect electrical connection, one or more intervening components such as switches, diodes, capacitors, inductors, resistors, other suitable components, or combinations thereof may be present between the terminals of the components in the two circuits, but the scope is not limited to these examples.

The terms ‘about,’ ‘equal to,’ ‘equal,’ or ‘substantially the same’ typically indicate a value or range within 20% of a specified value or range, or within 10%, 5%, 3%, 2%, 1%, or 0.5% of the specified value or range.

Furthermore, the phrase ‘range from a first value to a second value’ includes the first value, the second value, and all intermediate values within the range. While ordinal terms such as ‘first,’ ‘second,’ ‘third,’ etc., may be used to describe various elements, these terms are not intended to impose any specific limitation on the elements. Instead, they are solely for distinguishing one element from another within the specification. In the claims, these ordinal terms may also denote the order in which elements are defined rather than their sequence or priority. For example, a component described as the ‘first element’ in the description may be referred to as the ‘second element’ in the claims, depending on the context.

It should be noted that in the embodiments listed below, the technical features in several different embodiments may be substituted, rearranged, or combined without departing from the spirit of the disclosure or creating conflicts, thereby forming additional embodiments.

The electronic device may include, but is not limited to, a display device, a backlight device, an antenna device, a sensing device, or a splicing device. The electronic device may also be a bendable or flexible device. The display device may be either a non-self-luminous or self-luminous display device. The antenna device may be a liquid crystal type or a non-liquid crystal type antenna device. The sensing device may detect various parameters, such as capacitance, light, heat energy, or ultrasonic waves, but is not limited to these examples. The electronic device may also include electronic units comprising both passive components (e.g., capacitors, resistors, and inductors) and active components (e.g., diodes and transistors). Diodes may include light-emitting diodes (LEDs) or photodiodes. The light-emitting diodes may further include, for example, organic light-emitting diodes (OLEDs), mini LEDs, micro LEDs, or quantum dot LEDs, but are not limited thereto. The splicing device may be, for instance, a display splicing device or an antenna splicing device, but is not restricted to these types. It should be noted that the electronic device may consist of any of the above-mentioned configurations, arrangements, and combinations, without limitation. For illustrative purposes, a display device will be used as an example of an electronic device in the following description. However, the disclosure is not limited to this example.

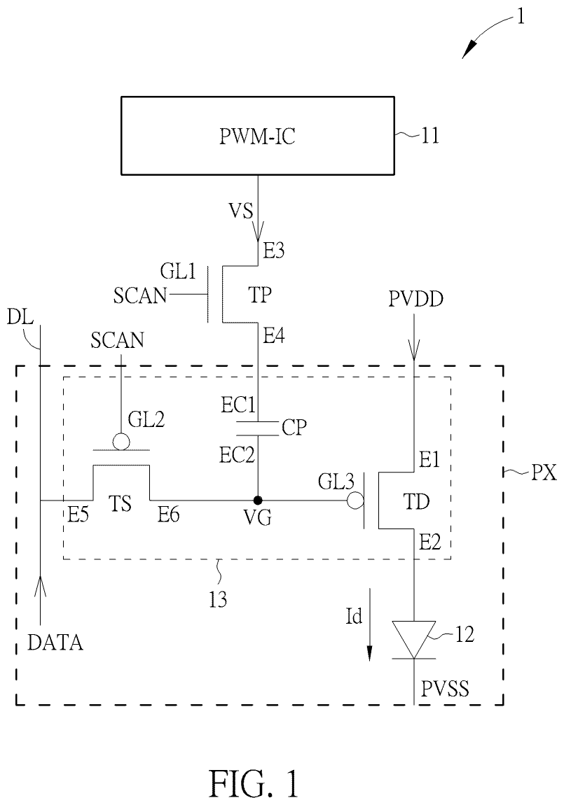

FIG. 1 is a schematic diagram of a circuit of an electronic device 1 according to an embodiment of the disclosure. The electronic device 1 may include a pulse width modulation integrated circuit (PWM-IC) 11, a transistor TP, a transistor TD, a transistor TS, a capacitor CP and an electronic unit 12. The pulse width modulation integrated circuit 11 may be configured to modulate the pulse width of the output signal. For clarity, the transistor TP is referred to as the sweeping transistor TP, the transistor TD as the driving transistor TD, and the transistor TS as the switching transistor TS; however, these designations are not intended to be limiting. The driving transistor TD, the switching transistor TS, and the capacitor CP may collectively form a pulse amplitude modulation (PAM) circuit 13. The PAM circuit 13, in combination with the electronic unit 12, may form a pixel PX. The sweeping transistor TP may be an N-type transistor, while the driving transistor TD and the switching transistor TS may be P-type transistors. However, these configurations are provided as examples and are not intended to limit the scope of the disclosure. Additionally, the pulse width modulation integrated circuit 11 may be configured to provide a sweep signal VS.

The driving transistor TD includes a first terminal E1, a second terminal E2, and a first control terminal GL3 (the terminals E1, E2, and GL3 may function as electrodes). The first terminal E1 is electrically connected to a power source to receive a voltage PVDD, while the second terminal E2 is electrically connected to the electronic unit 12. The sweeping transistor TP includes a third terminal E3, a fourth terminal E4, and a second control terminal GL1 (the terminals E3, E4, and GL1 may also function as electrodes). The third terminal E3 is electrically connected to the pulse width modulation integrated circuit 11 to receive the sweep signal VS. The fourth terminal E4 is electrically connected to the first control terminal GL3 of the driving transistor TD, and the second control terminal GL1 is configured to receive the switch signal SCAN. In some embodiments, the switch signal SCAN may be a square wave, although the disclosure is not limited to this configuration. The switching transistor TS includes a fifth terminal E5, a sixth terminal E6, and a third control terminal GL2 (the terminals E5, E6, and GL2 may also function as electrodes). The fifth terminal E5 is electrically connected to a data line DL to receive a data signal DATA. The sixth terminal E6 is electrically connected to the first control terminal GL3 of the driving transistor TD, and the third control terminal GL2 is configured to receive the switch signal SCAN. The capacitor CP includes a first terminal EC1 and a second terminal EC2. The first terminal EC1 is electrically connected to the fourth terminal E4 of the sweeping transistor TP, and the second terminal EC2 is electrically connected to the first control terminal GL3 of the driving transistor TD. The electronic unit 12 includes a first terminal and a second terminal. The first terminal is electrically connected to the second terminal E2 of the driving transistor TD, and the second terminal is connected to a ground, such as a voltage PVSS. The voltage PVSS is lower than the voltage PVDD. For example, PVDD may be 5 volts (V), and PVSS may be 0V.

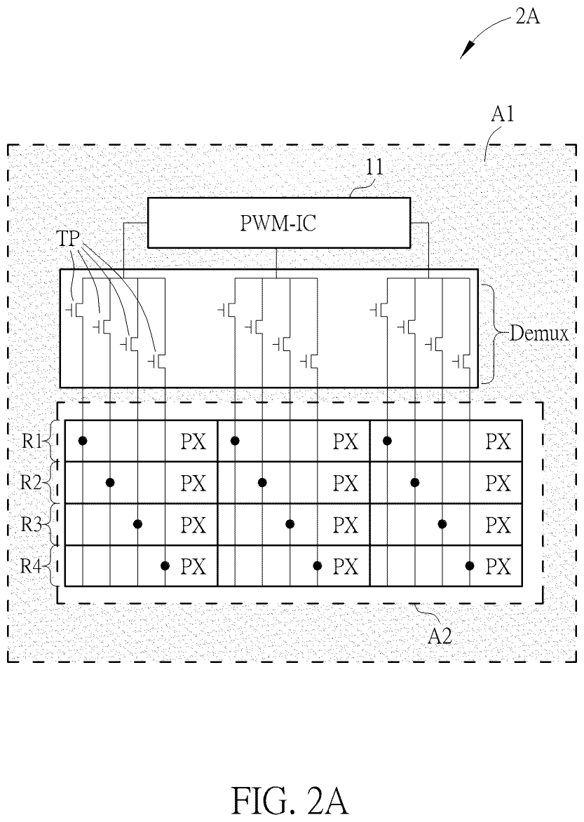

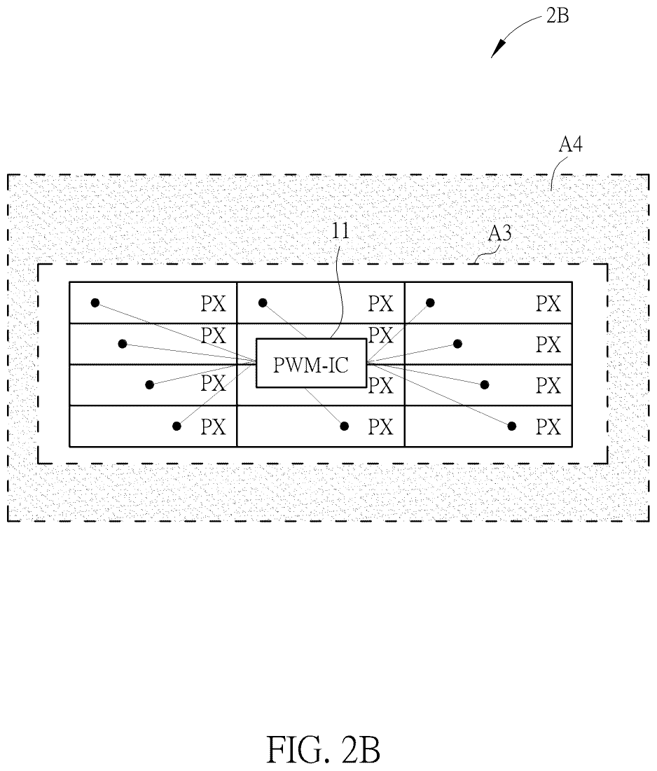

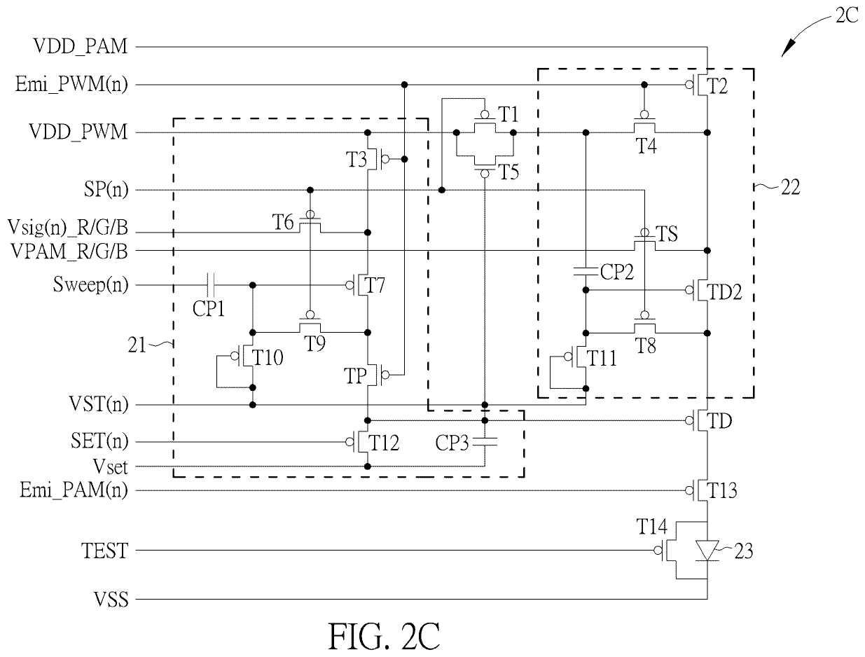

The pulse width modulation integrated circuit 11 may be implemented as an integrated circuit (IC), a micro integrated circuit (Micro IC), a chip, or a die. In some embodiments, the pulse width modulation integrated circuit 11 may be replaced with a plurality of thin film transistors (TFTs), as illustrated in FIG. 2C and explained in subsequent paragraphs. The characteristics of the electronic unit 12 may vary based on the magnitude of the data signal DATA. In some embodiments, the electronic unit 12 may be configured to receive or emit electromagnetic waves. For example, the electronic unit 12 may be a light-emitting diode (LED) or a varactor diode. If the electronic unit 12 is implemented as a light-emitting diode, the first terminal of the electronic unit 12 may serve as the anode, and the second terminal may serve as the cathode.

During the operational period of the electronic unit 12, such as a light-emission period, the voltage value of the sweep signal VS may vary over time with a constant slope, either increasing or decreasing. In certain embodiments, the sweeping transistor TP may be positioned within the pixel PX. Alternatively, in other embodiments, the sweeping transistor TP may be located outside the pixel PX.

The data signal DATA may be a voltage signal, with the voltage value in the data signal DATA ranging between the voltage PVSS and the voltage PVDD. For example, the voltage value may represent a pixel grayscale value. When the switching transistor TS is turned on, the switching transistor TS passes the data signal DATA from the data line DL to the second terminal EC2 of the capacitor CP, thereby setting the initial voltage at the second terminal EC2 of the capacitor CP. Once the switching transistor TS is turned off, the switching transistor TS isolates the data signal DATA, preventing further updates to the voltage value at the second terminal EC2 of the capacitor CP. The voltage at the second terminal EC2 of the capacitor CP serves as the gate voltage VG for the first control terminal GL3 (the gate) of the driving transistor TD. The gate voltage VG directly affects the degree to which the driving transistor TD is turned on, thereby influencing the magnitude of the current Id. When the electronic unit 12 is implemented as a light-emitting diode (LED), the magnitude of the current Id determines the brightness of the electronic unit 12. Specifically, when the voltage difference between PVDD and the gate voltage VG is large, the driving transistor TD is highly turned on, resulting in a larger current Id and increased brightness of the electronic unit 12. Conversely, when the voltage difference between PVDD and VG is small, the driving transistor TD is less turned on, leading to a smaller current Id and reduced brightness of the electronic unit 12. If the voltage difference between PVDD and VG becomes negative, the driving transistor TD is completely turned off, causing the current Id to drop to zero, and the electronic unit 12 ceases operation. Since the magnitude of the current Id is influenced by the voltage value of the data signal DATA, the switching transistor TS, the driving transistor TD, and the capacitor CP collectively function as a pulse amplitude modulation (PAM) circuit 13.

When the sweeping transistor TP is turned on, the sweep signal VS is transmitted to the first terminal EC1 of the capacitor CP, thereby altering the voltage at the second terminal EC2 of the capacitor CP. If the sweep signal VS is a voltage that increases with a constant slope over time, the voltage at the second terminal EC2 of the capacitor CP will also increase accordingly. This results in a gradual decrease in the turn-on degree of the driving transistor TD. Once the driving transistor TD is turned off, the current Id decreases to 0 amperes (A), rendering the electronic unit 12 inactive. The light-emitting time interval of the electronic unit 12 is determined by the initial voltage of the second terminal EC2 of the capacitor CP and the slope of the sweep signal VS, thereby achieving the effect of pulse width modulation (PWM). For the same sweep signal VS, a higher initial voltage at the second terminal EC2 of the capacitor CP results in a longer light-emitting time interval for the electronic unit 12, whereas a lower initial voltage results in a shorter light-emitting time interval. Conversely, for the same initial voltage at the second terminal EC2 of the capacitor CP, a steeper slope of the sweep signal VS leads to a shorter light-emitting time interval for the electronic unit 12, while a gentler slope of the sweep signal VS leads to a longer light-emitting time interval.

The electronic device 1 may utilize both pulse amplitude modulation (PAM) and pulse width modulation (PWM) to independently or simultaneously control the magnitude of the current Id and the light-emitting time interval. This enables precise control of pixel grayscale values, resulting in more accurate brightness levels. Since the electronic device 1 includes multiple pixels PX, sharing the sweep signal VS among the pixels PX allows for a reduction in the number of thin film transistors, thereby conserving space.

As the sweeping transistor TP provides the signal to turn off the driving transistor TD, the switching speed of the driving transistor TD plays a critical role in achieving precise grayscale control. If the switching speed of the sweeping transistor TP is too slow, the driving transistor TD may experience a delay before completely turning off after the voltage difference between PVDD and the gate voltage VG reaches the threshold voltage of the driving transistor TD. This delay can result in inaccurate control of pixel grayscale values. In this embodiment, the switching speed of the sweeping transistor TP is set faster than that of the driving transistor TD. For instance, when the voltage difference between PVDD and VG reaches the threshold voltage of the driving transistor TD (e.g., 0.7V), the driving transistor TD is instantly turned off. This ensures improved accuracy in controlling the display pixel grayscale values, particularly for low grayscale levels.

The ratio of the slew rate (i.e., the rate of change of voltage during transistor switching) at the control terminals of the sweeping transistor TP and the driving transistor TD may range between 0.79 and 2.01. This ratio can be adjusted based on the materials or specific combinations of thin film transistors used.

According to the embodiments of the disclosure, when the slew rate ratio of the driving transistor TD to the sweeping transistor TP is between 0.79 and 2.01, improved low-grayscale switching control can be achieved. Furthermore, when the slew rate ratio is refined to a range between 1.01 and 1.7, enhanced display performance can be obtained.

FIG. 2A is a schematic diagram of an electronic device 2A according to another embodiment of the disclosure. The electronic device 2A is divided into two regions: a surrounding area A1 and a main area A2. The surrounding area A1 encircles the main area A2. In the electronic device 2A, a plurality of pixels PX is positioned within the main area A2, while the pulse width modulation integrated circuit 11 and the demultiplexer (Demux) are located in the surrounding area A1. The pulse width modulation integrated circuit 11 is connected to the plurality of pixels PX via the demultiplexer Demux, enabling row-by-row control of the pixels PX. For example, the sweep signal VS may be sequentially transmitted to the pixels PX in rows, such as from the first row R1 to the fourth row R4. The demultiplexer Demux may include a plurality of sweeping transistors TP, with each sweeping transistor TP coupled to a corresponding pixel PX. In some embodiments, the sweeping transistors TP may be high mobility oxide (HMO) transistors to facilitate fast switching and/or low leakage performance. The driving transistor TD is positioned in the main area A2, within the region containing the pixel PX.

FIG. 2B is a schematic diagram of an electronic device 2B according to another embodiment of the disclosure. The electronic device 2B is divided into two regions: a surrounding area A4 and a main area A3, with the surrounding area A4 encircling the main area A3. A plurality of pixels PX is positioned in the main area A3. The pulse width modulation integrated circuit 11 is also located in the main area A3, corresponding to the position of the pixels PX. For instance, the pulse width modulation integrated circuit 11 may be situated centrally among the plurality of pixels PX within the main area A3. The pulse width modulation integrated circuit 11 is electrically connected to each pixel PX via wiring. Each pixel PX may include a sweeping transistor TP, which may be implemented as a high mobility oxide transistor. The driving transistor TD is also positioned in the main area A3, within the region containing the pixel PX.

FIG. 2C is a schematic diagram of a circuit of an electronic device 2C according to another embodiment of the disclosure. The electronic device 2C includes a pulse width modulation integrated circuit 21, a pulse amplitude modulation integrated circuit 22, a driving transistor TD, a transistor T1, a transistor T5, a transistor T13, a transistor T14, and an electronic unit 23. In this embodiment, the pulse width modulation integrated circuit 21 is composed of thin film transistors and may include a sweeping transistor TP, a transistor T3, a transistor T6, a transistor T7, a transistor T9, a transistor T10, a transistor T12, a capacitor CP1, and a capacitor CP3. The pulse amplitude modulation integrated circuit 22 may include a driving transistor TD2, a transistor T2, a transistor T4, a transistor T8, a transistor T11, a capacitor CP2, and a switching transistor TS.

VDD_PAM represents the supply voltage for the pulse amplitude modulation integrated circuit 22, while VDD_PWM represents the supply voltage for the pulse width modulation integrated circuit 21. Emi_PWM(n) is a signal used to control the light emission of the pulse width modulation integrated circuit 21, and Emi_PAM(n) is a signal used to control the light emission of the pulse amplitude modulation integrated circuit 22. VST(n) is a signal (e.g., −4 V) applied to the sub-pixel circuit 110 to initialize the voltage at the gate terminals of the driving transistor T12 and the driving transistor T8. When being initialized by the VST(n) signal, the driving transistor T12 and the driving transistor T8 may be turned on. Following the initialization, the SP(n) signal is applied. The SP(n) signal is a control signal applied to the sub-pixel circuit 110 to set (or program) the image data voltage, which may include a PWM data voltage or a constant current generator data voltage. Vsig(n)_R/G/B represents the RGB data signals used by the pulse width modulation integrated circuit 21, while VPAMR/G/B represents the RGB data signals used by the pulse amplitude modulation integrated circuit 22. Sweep(n) refers to the original control signal, which is subsequently modulated with the data signal to achieve the desired slew rate. SET(n) is a signal applied to the gate terminal to allow the Vset signal to pass. Vset is a voltage setting signal (e.g., −4 V). The SET(n) signal resets the capacitor and enables the emission signal of the first driving transistor TD (T2), preparing the circuit to transmit the sweep signal Vs generated by the PWM in the next timing sequence.

The TEST signal is used in a bypass mode for testing purposes, allowing verification of the operational status of the electronic unit 23 or the electronic device 2C. VSS is the ground voltage, typically 0V.

The sweeping transistor TP includes a control terminal configured to receive the signal Emi_PWM(n), a first terminal, and a second terminal. The switching transistor TS includes a first terminal configured to receive the signal VPAMR/G/B, a control terminal configured to receive the signal SP(n), and a second terminal.

The driving transistor TD2 includes a control terminal, a first terminal coupled to the second terminal of the switching transistor TS, and a second terminal. The driving transistor TD includes a control terminal coupled to the second terminal of the sweeping transistor TP, a first terminal coupled to the second terminal of the driving transistor TD2, and a second terminal.

The transistor T1 includes a control terminal for receiving the signal SP(n); a first terminal for receiving the signal VDD_PWM; and a second terminal. The transistor T2 includes a control terminal for receiving the signal Emi_PWM(n); a first terminal for receiving the VDD_PAM; and a second terminal coupled to the first terminal of the driving transistor TD2. The transistor T3 includes a control terminal for receiving the signal Emi_PWM(n); a first terminal for receiving the signal VDD_PWM; and a second terminal. The transistor T4 includes a control terminal for receiving the signal Emi_PWM(n); a first terminal coupled to the second terminal of the transistor T1; and a second terminal coupled to the first terminal of the driving transistor TD2. The transistor T5 includes a control terminal for receiving the signal VST(n); a first terminal for receiving the signal VDD_PWM; and a second terminal coupled to the first terminal of the transistor T4. The transistor T6 includes a control terminal for receiving the signal SP(n); a first terminal for receiving the Vsig(n)_R/G/B; and a second terminal coupled to the second terminal of the transistor T3. The transistor T7 includes a control terminal; a first terminal coupled to the second terminal of the transistor T6; and a second terminal coupled to the first terminal of the sweeping transistor TP. The transistor T8 includes a control terminal for receiving the signal SP(n); a first terminal; and a second terminal coupled to the first terminal of the driving transistor TD. The transistor T9 includes a control terminal for receiving the signal SP(n); a first terminal coupled to the control terminal of the transistor T7; and a second terminal coupled to the first terminal of the sweeping transistor TP. The transistor T10 includes a control terminal for receiving the signal VST(n); a first terminal coupled to the first terminal of the transistor T9; and a second terminal for receiving the signal VST(n). The transistor T11 includes a control terminal for receiving the signal VST(n); a first terminal coupled to the first terminal of the transistor T8; and a second terminal for receiving the signal VST(n). The transistor T12 includes a control terminal for receiving the signal SET(n); a first terminal coupled to the second terminal of the sweeping transistor TP; and a second terminal for receiving the signal Vset. The transistor T13 includes a control terminal for receiving the signal Emi_PAM(n); a first terminal coupled to the second terminal of the driving transistor TD; and a second terminal. The transistor T14 includes a control terminal for receiving the signal TEST; a first terminal coupled to the second terminal of the transistor T13; and a second terminal for receiving the ground voltage VSS. The capacitor CP1 includes a first terminal for receiving the signal Sweep(n); and a second terminal coupled to the control terminal of the transistor T7. The capacitor CP2 includes a first terminal coupled to the second terminal of the transistor T1 and a second terminal coupled to the control terminal of the driving transistor TD2. The capacitor CP3 includes a first terminal coupled to the control terminal of the driving transistor TD; and a second terminal used to receive the signal Vset.

As described above, the slew rate ratio between the sweeping transistor TP and the driving transistor TD can significantly affect display performance. For instance, when the slew rate ratio of the driving transistor TD to the sweeping transistor TP is between 0.79 and 2.01, improved low-grayscale switching control can be achieved. When the ratio is between 1.01 and 1.7, optimal display performance may be achieved.

The slew rate is influenced by the dimensions of the transistor channel, specifically the channel width-to-length ratio (W/L). Since the slew rate is positively correlated with the W/L ratio of the transistor, the slew rate ratio of the driving transistor TD to the sweeping transistor TP is also directly proportional to the ratio of their respective W/L ratios. According to an embodiment of the disclosure, the ratio of the channel width-to-length ratio of the driving transistor TD to that of the sweeping transistor TP may range from 0.03 to 80.5. If this ratio is below the minimum value, it indicates that the slew rate of the driving transistor TD is too slow or the slew rate of the sweeping transistor TP is too steep, potentially causing indistinct low-grayscale switching in the display pixels. Conversely, if the ratio exceeds the maximum value, it indicates that the slew rate of the driving transistor TD is too steep or the slew rate of the sweeping transistor TP is too slow, potentially leading to a delay effect. This may cause the driving transistor TD to handle currents exceeding the rated value, resulting in current stress. In alternative embodiments, the ratio of the channel width-to-length ratio of the driving transistor TD to the sweeping transistor TP may range from 0.05 to 57.5. In another embodiment, the ratio may range from 0.2 to 17.3.

The slew rate of a transistor is positively correlated with the channel width-to-length ratio (W/L) of the transistor, and may also be influenced by the type of semiconductor material used. For example, when the semiconductor material is high mobility oxide (HMO), the slew rate may be lower compared to transistors made with indium gallium zinc oxide (IGZO). Similarly, the slew rate for IGZO-based transistors may be lower than for those using low-temperature polycrystalline silicon (LTPS) as the semiconductor material. In one embodiment, the electron mobility of the semiconductor materials is as follows: For HMO semiconductors, the electron mobility is approximately 30 cm²/V·s; for IGZO semiconductors, the electron mobility is approximately 5 cm²/V·s; and for LTPS semiconductors, the electron mobility is approximately 100 cm²/V·s. These differences in electron mobility directly affect the slew rate, with higher electron mobility corresponding to a higher slew rate for the transistor.

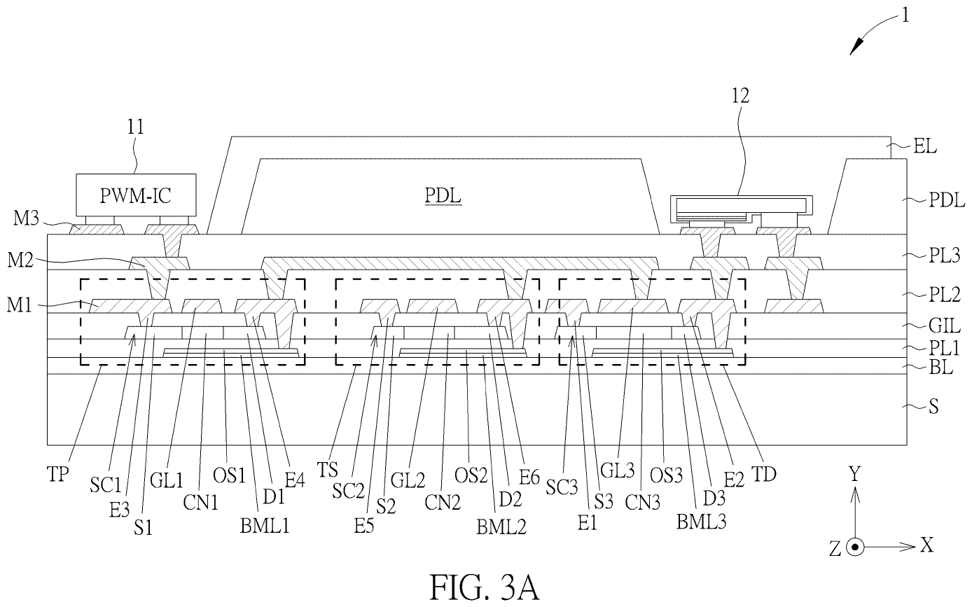

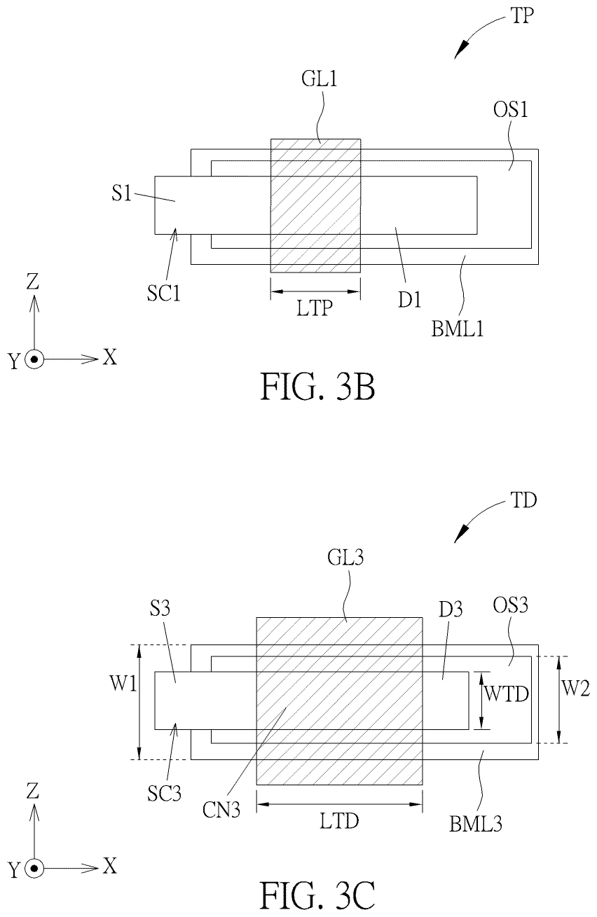

FIG. 3A is a cross-sectional view of the electronic device 1. The electronic device 1 comprises a pulse width modulation integrated circuit 11, an electronic device 12, a substrate S, a buffer layer BL, an insulating layer PL1, an insulating layer PL2, an insulating layer PL3, a gate insulating layer GIL, an encapsulation layer EL, a pixel definition layer PDL, a metal layer M1, a metal layer M2, a metal layer M3, a sweeping transistor TP, a switching transistor TS, and a driving transistor TD.

The buffer layer BL is disposed on the substrate S. The insulating layer PL1 is positioned on the buffer layer BL, and the gate insulating layer GIL is disposed on the insulating layer PL1. The insulating layer PL2 is positioned on the gate insulating layer GIL, and the insulating layer PL3 is disposed on the insulating layer PL2. The pixel definition layer PDL is positioned on the insulating layer PL3. The encapsulation layer EL covers the insulating layer PL3, the pixel definition layer PDL, and the electronic device 12. The metal layer M2 is positioned on the metal layer M1 and the insulating layer PL2, while the metal layer M3 is disposed on the metal layer M2 and the insulating layer PL3.

The sweeping transistor TP includes a metal oxide element OS1 and a semiconductor SC1. The semiconductor SC1 comprises a channel CN1, a source region S1, and a drain region D1. The switching transistor TS includes a metal oxide element OS2 and a semiconductor SC2. The semiconductor SC2 comprises a channel CN2, a source region S2, and a drain region D2. The driving transistor TD includes a metal oxide element OS3 and a semiconductor SC3. The semiconductor SC3 comprises a channel CN3, a source region S3, and a drain region D3. The driving transistor TD further includes a first terminal E1, a second terminal E2, and a first control terminal GL3. The second terminal E2 is electrically connected to the electronic unit 12. The sweeping transistor TP includes a third terminal E3, a fourth terminal E4, and a second control terminal GL1. The third terminal E3 is electrically connected to the pulse width modulation integrated circuit 11, and the fourth terminal E4 is electrically connected to the first control terminal GL3 of the driving transistor TD. The switching transistor TS includes a fifth terminal E5, a sixth terminal E6, and a third control terminal GL2. The sixth terminal E6 is electrically connected to the first control terminal GL3 and the fourth terminal E4. In another embodiment, the sweeping transistor TP may further include a light-shielding element BML1, the switching transistor TS may include a light-shielding element BML2, and the driving transistor TD may include a light-shielding element BML3.

At least one of the semiconductors SC1 and SC3 is an oxide semiconductor, such as an indium gallium zinc oxide (IGZO) semiconductor. In some embodiments, both SC1 and SC3 may be oxide semiconductors, such as high mobility oxide (HMO) semiconductors or IGZO semiconductors. For example, semiconductors SC1, SC2, and SC3 may all be IGZO materials, meaning the sweeping transistor TP, the switching transistor TS, and the driving transistor TD are all IGZO transistors. In another example, SC1 and SC3 may both be high mobility oxide materials, making the sweeping transistor TP and the driving transistor TD HMO transistors. HMO transistors feature a lower threshold voltage, and can improve switching speed and the conductive properties of transistor components. The semiconductor SC2 may also be an oxide semiconductor. In some embodiments, even if both SC1 and SC3 are oxide semiconductors, they may be composed of the same elements but in different proportions. For instance, while both SC3 (in the driving transistor TD) and SC1 (in the sweeping transistor TP) may be IGZO semiconductors, the gallium (Ga) content in SC3 could be higher than that in SC1.

FIG. 3B is a top view of the sweeping transistor TP depicted in FIG. 3A. As shown in FIG. 3B, the sweeping transistor TP includes a light-shielding element BML1, a metal oxide element OS1, a semiconductor SC1, and a second control terminal GL1. FIG. 3C is a schematic diagram of the driving transistor TD shown in FIG. 3A. As depicted in FIG. 3C, the driving transistor TD includes a light-shielding element BML3, a metal oxide element OS3, a semiconductor SC3, and a first control terminal GL3. Since the sweeping transistor TP and the driving transistor TD serve different functions, their channel lengths may vary accordingly. The channel length of a transistor is defined as the length of the overlapping region between the control terminals (e.g., GL1 or GL3) and the semiconductor layers (e.g., SC1 or SC3). The channel length direction extends from the source region to the drain region within the respective semiconductor layer. As the driving transistor TD is responsible for driving control and performing low-grayscale control, the channel length LTD of the driving transistor TD needs to be longer. Conversely, the sweeping transistor TP primarily handles switching to allow signals from the integrated circuit to pass through. To prevent distortion of the signals transmitted by the integrated circuit, the channel length LTP of the sweeping transistor TP needs to be shorter. Similarly, the switching transistor TS requires a shorter channel length to avoid distortion of the transmitted data signal. Accordingly, the channel length LTD of the driving transistor TD is greater than the channel length LTP of the sweeping transistor TP and/or the channel length of the switching transistor TS. The ratio of the channel length LTD of the driving transistor TD to the channel length LTP of the sweeping transistor TP may range from 1.05 to 3.5. In some embodiments, this ratio may range from 1.1 to 2.2.

The metal oxide element OS3 of the driving transistor TD may overlap the semiconductor SC3. The semiconductor SC3, which may be an oxide semiconductor, is positioned between the first control terminal GL3 and the metal oxide element OS3. When viewed from above, the width W2 of the metal oxide element OS3 is greater than the width of the semiconductor SC3. Consequently, the width W2 of the metal oxide element OS3 is greater than the channel width WTD of the driving transistor TD. The direction of the width is perpendicular to the direction of the channel length. As shown in FIG. 3C, the channel width WTD of the driving transistor TD is the width of the overlapping region between the first control terminal GL3 and the semiconductor SC3. The light-shielding element BML3 of the driving transistor TD may overlap the semiconductor SC3, with the metal oxide element OS3 positioned between the semiconductor SC3 and the light-shielding element BML3. The light-shielding element BML3 may directly contact the metal oxide element OS3, and the width W1 of the light-shielding element BML3 is greater than the width W2 of the metal oxide element OS3. The measured directions of the width W1 of the light-shielding element BML3, the width W2 of the metal oxide element OS3, and the channel width WTD of the driving transistor TD are all perpendicular to the measured direction of the channel length LTD of the driving transistor TD. The light-shielding element BML3 is configured to reduce the likelihood of the channel CN3 being exposed to external light and/or minimize the impact of reflected light on the semiconductor SC3, thereby mitigating adverse effects on the electronic characteristics of the driving transistor TD. The metal oxide element OS3 may be located beneath the channel CN3 of the driving transistor TD and may provide oxygen atoms to the channel CN3 to mitigate the negative bias instability of the threshold voltage. The metal oxide element OS3 may include at least one metal oxide element selected from indium (In), zinc (Zn), gallium (Ga), and tin (Sn). For example, the metal oxide element OS3 may comprise materials such as indium gallium zinc oxide (IGZO), indium tin oxide (ITO), indium tin gallium oxide (ITGO), indium zinc oxide (IZO), zinc oxide (ZnO), or indium tin gallium zinc oxide (ITGZO). The light-shielding element BML3 may include at least one material selected from aluminum (Al), silver (Ag), magnesium (Mg), gold (Au), nickel (Ni), chromium (Cr), calcium (Ca), and molybdenum (Mo). Similarly, the materials used for the metal oxide elements OS1 and OS2 may be the same as or different from the metal oxide element OS3. Likewise, the materials used for the light-shielding elements BML1 and BML2 may be the same as or different from the light-shielding element BML3. The present disclosure is not limited to these configurations or materials.

To address electrical instability issues in HMO transistors, such as negative bias problems in threshold voltage and/or early turn-on, the semiconductor of the HMO transistor may be positioned between the control terminal and the metal oxide element. This arrangement allows the metal oxide element to repair oxygen void zones in the transistor channel. To ensure stable repair, the metal oxide element may be designed with different areas corresponding to the distinct functional requirements of the driving transistor TD and the sweeping transistor TP. The metal oxide element OS3 of the driving transistor TD may overlap with the semiconductor SC3, while the metal oxide element OS1 of the sweeping transistor TP may overlap with the semiconductor SC1. The area of the metal oxide element OS3 may be larger than the area of the metal oxide element OS1. The metal oxide elements OS1 to OS3 are positioned at a distance from the metal layers M1 to M3 (which are disposed above the metal oxide elements OS1 to OS3), ensuring that the channels CN1 to CN3 respectively fully overlap with the metal oxide elements OS1 to OS3, thereby reducing interference from the metal layers M1 to M3. The ratio of the area of the metal oxide element OS3 in the driving transistor TD to the area of the metal oxide element OS1 in the sweeping transistor TP may range from 1.1 to 10.2. If this ratio is too small, it may lead to electrical instability in the driving transistor TD. Conversely, if the ratio is too large, it may result in abnormal operation of the sweeping transistor TP. In some embodiments, the channel characteristics of different transistors may also be adjusted by selecting specific materials for the insulating layers PL1 and PL2. For example, the insulating layers PL1, PL2, PL3, and the gate insulating layer GIL may be oxide materials, but this is not limiting. In other embodiments, to mitigate the negative bias instability of the threshold voltage caused by HMO transistors, at least one insulating layer (e.g., insulating layer PL1 or gate insulating layer GIL) adjacent to the transistor channel may be an insulating oxide layer, such as silicon oxide or aluminum oxide, although other materials may also be used.

The first control terminal (GL3) primarily controls the electrical driving status of the driving transistor (TD), which is mainly responsible for the operation of electronic units (e.g., light emission). To achieve precise low-grayscale control, the slew rate ratio between the driving transistor TD and the sweeping transistor TP needs to be lower, requiring a longer channel length LTD for the driving transistor TD. Additionally, for high-brightness applications, the channel width of the driving transistor TD must be increased. As a result, the area of the driving transistor TD needs to be larger than the area of the sweeping transistor TP to ensure sufficient electrical driving capability. The area of a transistor is defined as the overlapping region between the control terminal and the semiconductor of the transistor. Given the limited available space, the ratio of the area of the driving transistor TD to the area of the sweeping transistor TP may range from 1.2 to 7.6. If this ratio is too small, the light emission characteristics of the electronic unit may be suboptimal. Conversely, if the ratio is too large, excessive overlap between the driving transistor TD and other transistors or traces may occur, leading to issues such as excessive stray capacitance.

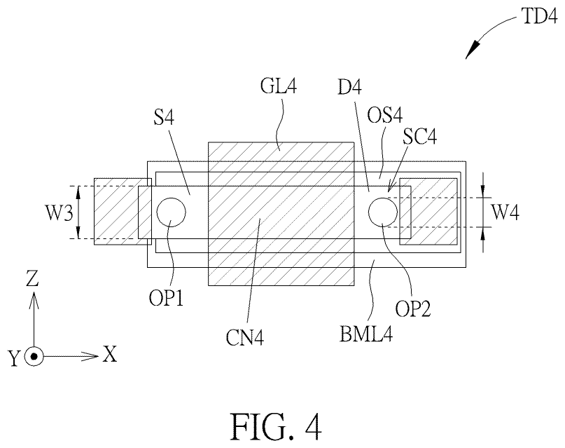

FIG. 4 illustrates a top view of a driving transistor TD4 according to another embodiment of the disclosure. In this embodiment, to mitigate current stress caused by current concentration, openings OP1 and OP2 are created in the source region S4 and the drain region D4 of the semiconductor SC4 of the driving transistor TD4. As shown in FIG. 4, the openings OP1 and OP2 are positioned on opposite sides of the channel CN4 of the driving transistor TD4. These openings are designed to distribute the current, preventing excessive current concentration. From the top view of the electronic device, the control terminal GL4 is located between the opening OP1 and the opening OP2. To ensure process stability, the openings OP1 and OP2 are positioned on the metal oxide element OS4. Specifically, the openings OP1 and OP2 overlap the metal oxide element OS4, and parts of the metal oxide element OS4 may be visible through the openings OP1 and OP2 in a top view. To avoid signal interruption, the width W4 of the opening OP2, measured in the direction perpendicular to the channel length of the transistor TD4, is smaller than the width W3 of the semiconductor SC4. This ensures that the semiconductor SC4 remains intact and continuous, preventing fractures that could disrupt signal transmission. The width of the opening OP1 is similar, and further details are omitted for brevity.

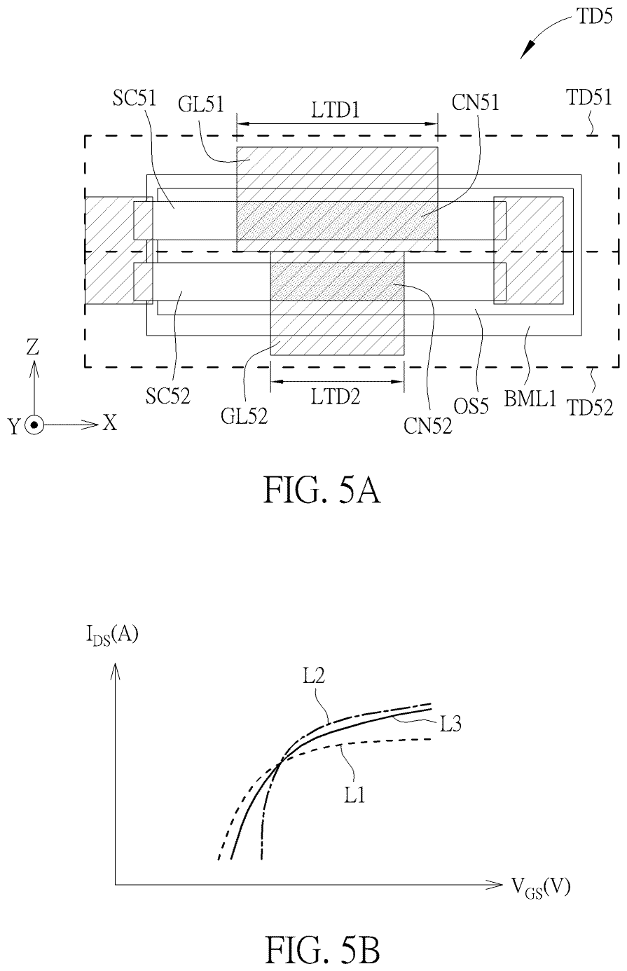

FIG. 5A illustrates a top view of a driving transistor TD5 according to another embodiment of the disclosure. In this embodiment, the driving transistor TD5 includes two parallel transistors, TD51 and TD52. The configuration of the transistor TD51 is similar to that of the driving transistor TD in FIG. 1 and will not be described in detail here. The transistor TD52 has a control terminal GL52 that is electrically connected to the control terminal GL51 of the transistor TD51. The transistor driving TD51 includes a semiconductor SC51, the semiconductor SC51 contains a channel CN51. Similarly, the driving transistor TD52 includes a semiconductor SC52, the semiconductor SC52 contains a channel CN52. The channel CN51 and the channel CN52 have different channel lengths and are connected in parallel. The channel length of CN51 is denoted as LTD1, while the channel length of CN52 is denoted as LTD2, where LTD1 is greater than LTD2.

In this embodiment, the sweeping transistor TP still contains only a single channel. However, the configuration of the driving transistor TD5 differs from that of the sweeping transistor TP. The driving transistor TD5 employs two parallel channels, CN51 and CN52, with different channel lengths. This arrangement allows for flexible current distribution, enabling the driving transistor TD5 to maintain a slow slew rate at a low gate-to-source voltage (low grayscale) while simultaneously achieving the required current generation capacity of the current Id at a high gate-to-source voltage (high grayscale).

FIG. 5B is a schematic diagram illustrating the current curve of the driving transistor TD5 depicted in FIG. 5A. The horizontal axis represents the gate-to-source voltage Vas in volts (V), while the vertical axis represents the drain-to-source current Ips in amperes (A). As shown in FIG. 5B, the channel CN51, with a longer channel length, and the channel CN52, with a shorter channel length, exhibit distinct current curves. The current curve of the channel CN51 is represented by curve L1, while the current curve of the channel CN52 is represented by curve L2. The overall current curve of the driving transistor TD5 during operation is represented by curve L3, which is a combination of curve L1 and curve L2. At low Vas values, the curve L3 resembles the curve L1 of the longer channel CN51, providing a slower slew rate suitable for low grayscale control. At high Vas values, the curve L3 becomes similar to the curve L2 of the shorter channel CN52, enabling sufficient Ips for high grayscale operation. By combining two parallel channels with different lengths, the driving transistor TD5 achieves a balanced performance that meets the requirements for both low and high grayscale operations, enhancing display performance.

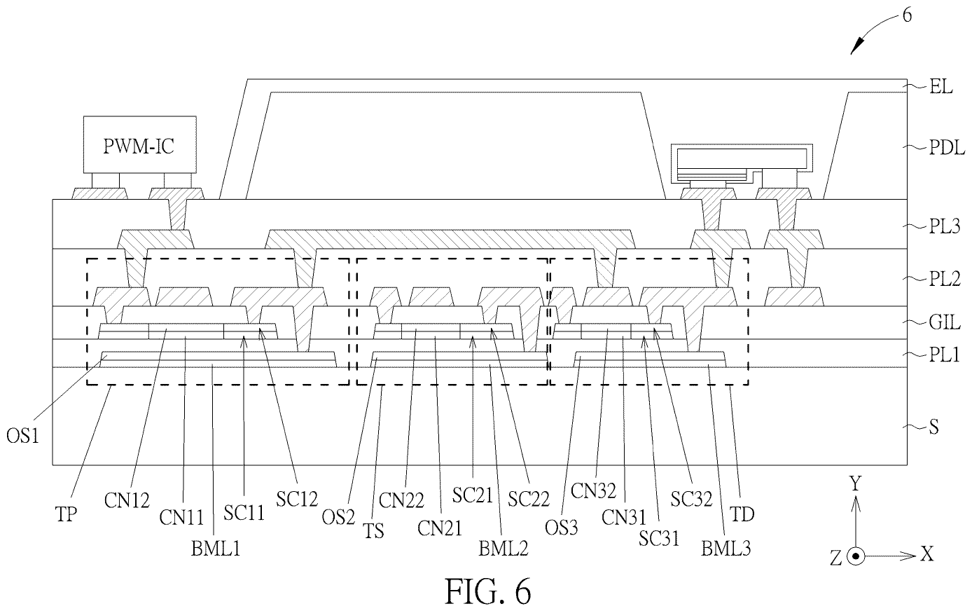

FIG. 6 is a cross-sectional view of an electronic device 6 according to another embodiment of the disclosure. As shown in FIG. 6, the semiconductor of the transistor may include multiple layers. The semiconductor of the driving transistor TD comprises a semiconductor layer SC31 and a semiconductor layer SC32, forming channels CN31 and CN32. The materials and/or composition ratios of the semiconductor layers SC31 and SC32 may differ. One of the semiconductor layers, such as SC31, may be made of a high-mobility oxide material, including but not limited to In—Zn—O, In—Ga—O, In—Ga—Zn—Sn—O, In—Ga—Sn—O, or In—Sn—Zn—O, with a higher proportion of indium (In). The other semiconductor layer, such as SC32, may consist of a more stable material, such as IGZO (In—Ga—Zn—O). This combination of semiconductor layers enables the adjustment of transistor mobility while maintaining stability. In one configuration, the semiconductor layer SC31, closer to the metal oxide element OS3, may be made of an HMO material, while the upper semiconductor layer SC32 may be made of IGZO. In some embodiments, each transistor may include three semiconductor layers, with the uppermost and lowermost layers made of IGZO for higher stability, and the middle layer made of an HMO material. A metal oxide element OS3 and a light-shielding element BML3 are disposed under the semiconductor SC31 of the driving transistor TD, with the metal oxide element OS3 stacked on the light-shielding element BML3. Similarly, the semiconductor of the sweeping transistor TP comprises a semiconductor layer SC11 and a semiconductor layer SC12, forming a channel CN11 and a channel CN12. The materials and proportions of SC11 and SC12 may differ, similar to those of the driving transistor TD. A metal oxide element OS1 and a light-shielding element BML1 are disposed under the semiconductor SC11, with the metal oxide element OS1 stacked on the light-shielding element BML1. The semiconductor of the switching transistor TS includes a semiconductor layer SC21 and a semiconductor layer SC22, forming a channel CN21 and a channel CN22. The materials and proportions of SC21 and SC22 may also vary, similar to those of the driving transistor TD. A metal oxide element OS2 and a light-shielding element BML2 are disposed under the semiconductor SC21, with the metal oxide element OS2 stacked on the light-shielding element BML2. The remaining configurations of the electronic device 6 are similar to those of the electronic device 1 shown in FIG. 3A and will not be described further.

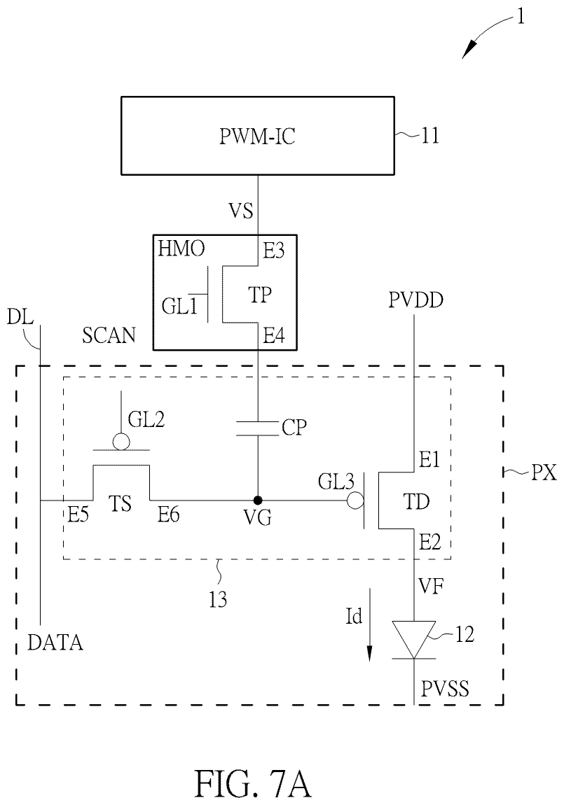

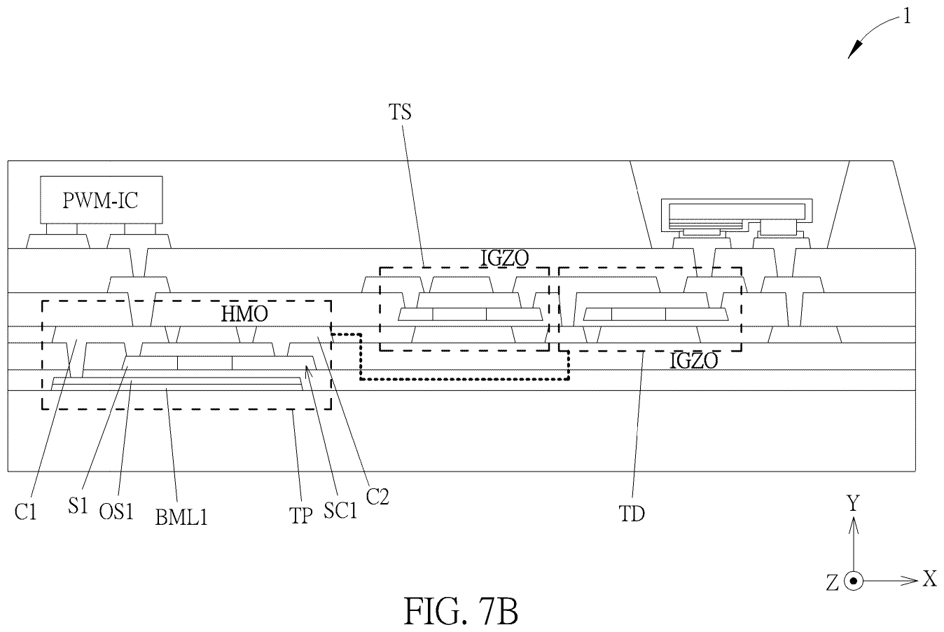

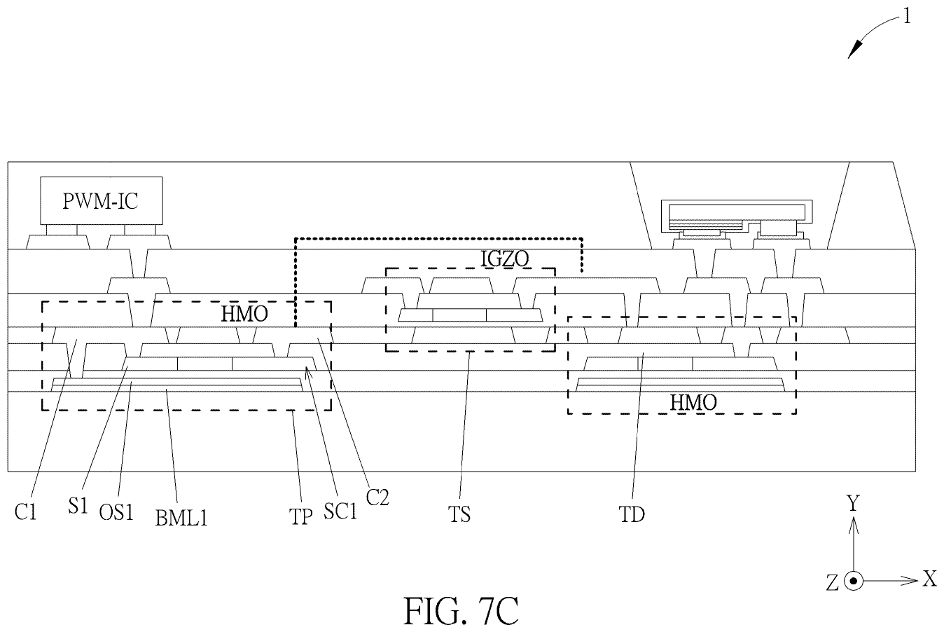

FIG. 7A illustrates a schematic diagram of a circuit for an electronic device 1 according to another embodiment of the disclosure. In this embodiment, the sweeping transistor TP of the electronic device 1 is implemented as an HMO transistor. Due to the low threshold voltage of HMO transistors, they enhance switching speed and conductive performance, facilitating instantaneous switching. The remaining configurations of the electronic device 1 are similar to those in FIG. 1 and will not be described again.

FIG. 7B shows a cross-sectional view of one embodiment of the electronic device 1 described in FIG. 7A, while FIG. 7C shows a cross-sectional view of another embodiment of the same device. In both FIG. 7B and FIG. 7C, the sweeping transistor TP is implemented as an HMO transistor. In FIG. 7B, to provide better driving stability for the pixels in the main area, the switching transistor TS and the driving transistor TD are made of IGZO semiconductors, which offer high stability and low leakage. Only the sweeping transistor TP is implemented as an HMO transistor. In FIG. 7C, to achieve higher resolution in the transistors within the main area, the driving transistor TD is also replaced by an HMO transistor. As shown in FIG. 7B and FIG. 7C, a metal oxide element OS1 is disposed under the semiconductor SC1 of the sweeping transistor TP and is electrically connected to the source region S1 of the semiconductor SC1 via a conductor C1, thereby stabilizing the threshold voltage. Depending on specific requirements, such as switching speed or stability, transistors made from different materials may be used in combination. Additionally, a conductor C2 may be electrically connected to the driving transistor TD.

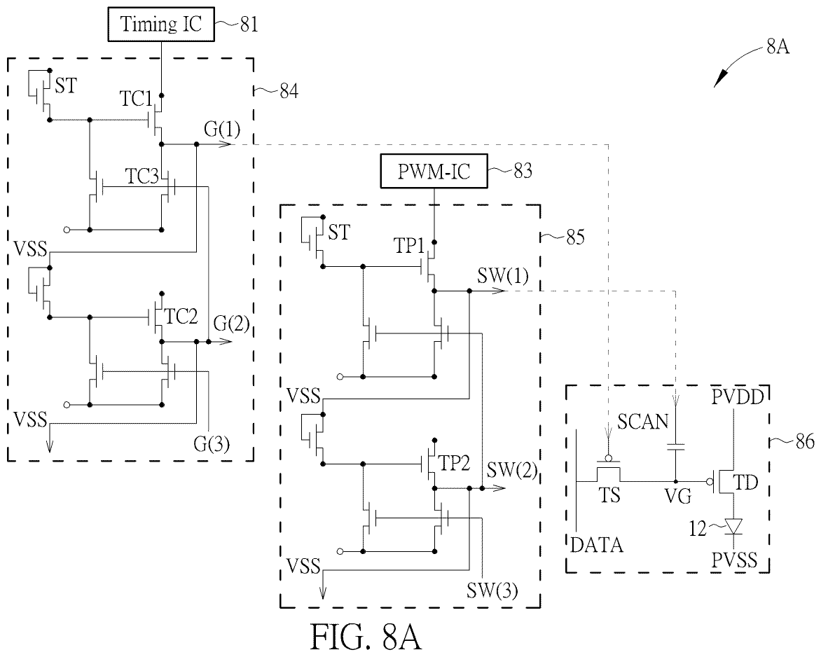

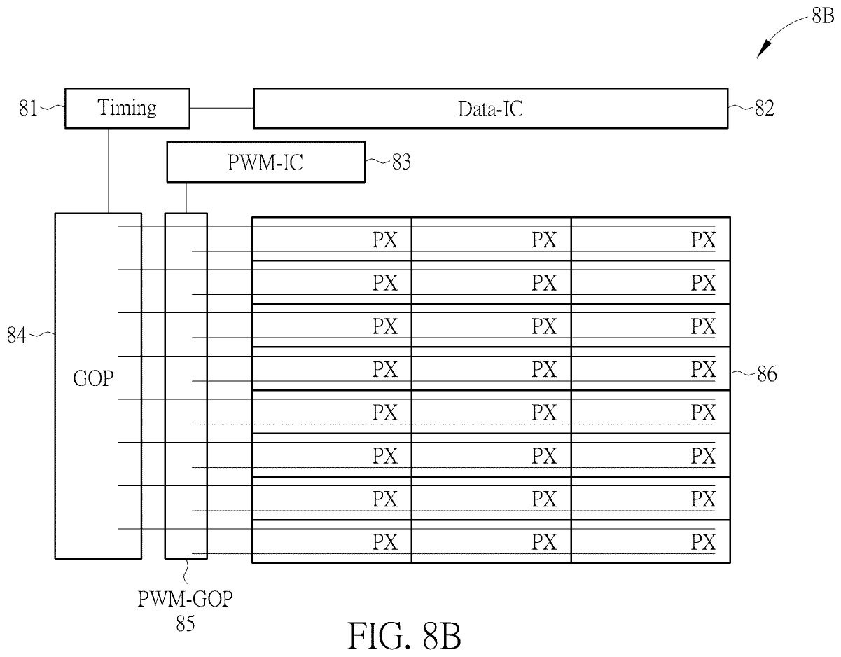

FIG. 8A illustrates a schematic diagram of a circuit for an electronic device 8A according to another embodiment of the disclosure. The circuit configuration of the electronic device 8A depicts the connection relationships among a timing IC 81, a pulse width modulation integrated circuit 83, a gate-on-panel (GOP) 84, a pulse width modulated gate-on-panel (PWM-GOP) 85, and the circuit configuration of an area 86 containing a plurality of pixels PX. The pulse width modulation integrated circuit 83 is configured to transmit signals to the sweeping transistor TP1, enabling the sequential update of control signals SW(1), SW(2), and SW(3). Additionally, the timing IC 81 transmits signals to the transistor TC1, enabling the sequential update of switch signals G(1), G(2), and G(3).

FIG. 8B illustrates a schematic diagram of an electronic device 8B according to another embodiment of the disclosure. As shown in FIG. 8B, the electronic device 8B includes a timing IC 81, a data IC 82, and a pulse width modulation integrated circuit (PWM-IC) 83, similar to the pulse width modulation integrated circuit 11 of the electronic device 1. In this embodiment, the gate circuit is integrated into the thin film transistor array to form a gate-on-panel (GOP) 84, rather than being implemented as a separate circuit component. This approach simplifies module design by fabricating the circuit directly within an electronic unit, such as a display panel. Since the switching requirements are high, and the GOP signal that drives the pixel gate in the main area is substantial, the GOP may be implemented using low-temperature polycrystalline silicon (LTPS). In some embodiments, a pulse width modulated gate-on-panel (PWM-GOP) 85 may be connected to facilitate continuous switching, and the PWM-GOP 85 may be implemented using the high-mobility oxide process. To achieve better stability and uniformity for large panels, the area 86 containing a plurality of pixels PX may be implemented using indium gallium zinc oxide process. The above description represents an example embodiment of the disclosure, and the actual material selection for the transistors is not limited to these options. In this configuration, the electronic device 8B includes the GOP 84 and the PWM-GOP 85 positioned on the same side, with each made of different types of transistors. This arrangement reduces signal interference between the components. It should be noted that FIG. 8B is a schematic representation of the electronic device 8B according to the embodiment of the disclosure, and the actual configuration is not limited to this illustration.

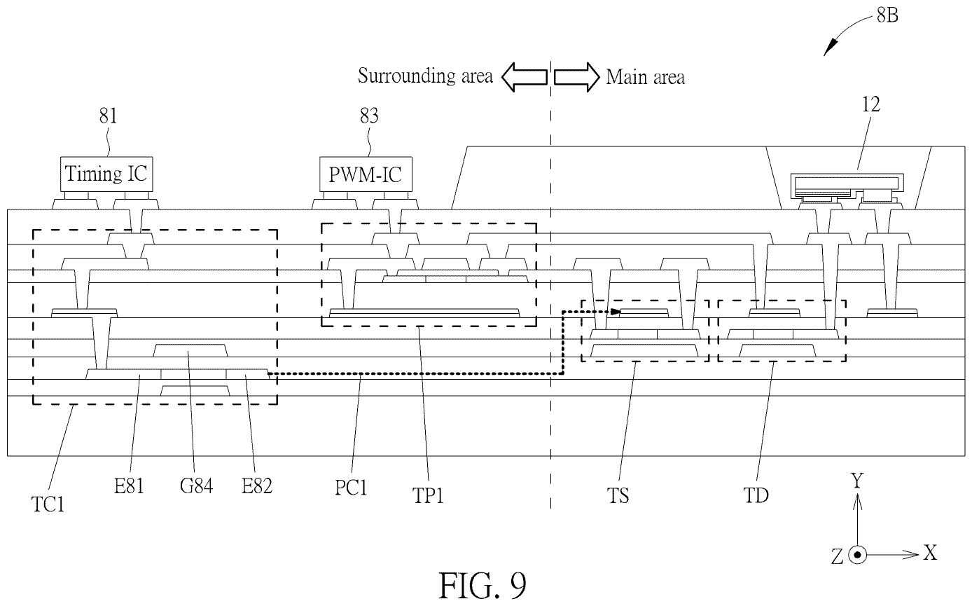

FIG. 9 is a cross-sectional view of the electronic device 8B illustrated in FIG. 8B. As shown in FIG. 9, the electronic device 8B is divided into a surrounding area and a main area. The switching transistor TS, the driving transistor TD, and the electronic unit 12 are located in the main area, while the timing IC 81, the pulse width modulation integrated circuit 83, the GOP 84, which includes the transistor TC1, and the PWM-GOP 85, which includes the transistor TP1, are located in the surrounding area. The timing IC 81 is electrically connected to the transistor TC1. The transistor TC1 comprises a first terminal E81, a second terminal E82, and a control terminal G84. The second terminal E82 of the transistor TC1 is electrically connected to the switching transistor TS via an electrical connection path PC1. The pulse width modulation integrated circuit 83 is electrically connected to the sweeping transistor TP1. The sweeping transistor TP1 is further electrically connected to the driving transistor TD, enabling control of the driving transistor TD. The driving transistor TD, in turn, is electrically connected to the electronic unit 12 to regulate the brightness of the electronic unit 12 by controlling the current flow.

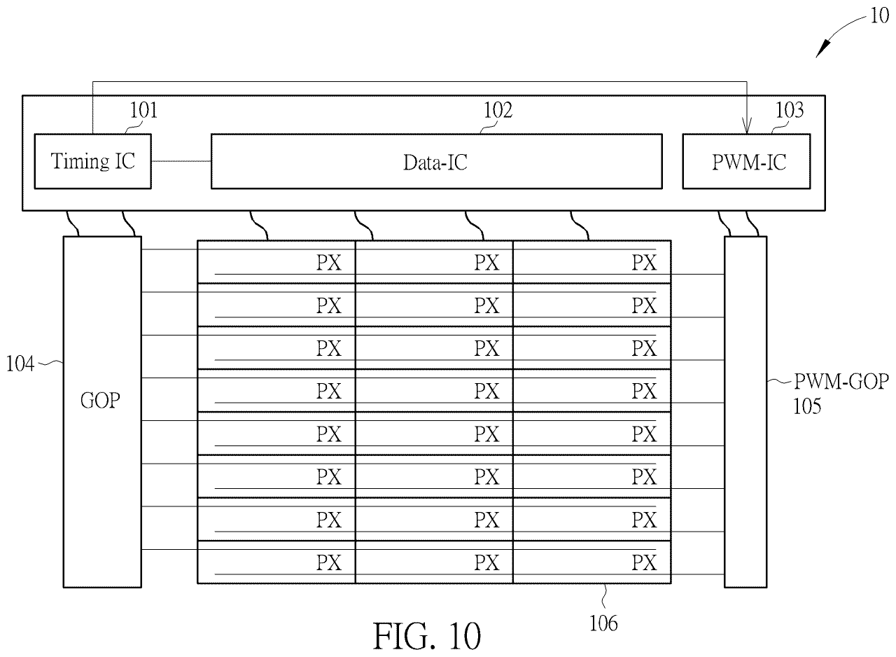

FIG. 10 illustrates a schematic diagram of an electronic device 10 according to another embodiment of the disclosure. As shown in FIG. 10, the electronic device 10 includes a timing IC 101, a data IC 102, and a PWM-IC 103. The electronic device 10 also incorporates a gate-on-panel (GOP) 104 and a PWM-GOP 105 for continuous switching. The primary distinction between the electronic device 10 and the electronic device 8B is the placement of the GOP 104 and the PWM-GOP 105. In the electronic device 10, the GOP 104 and the PWM-GOP 105 are positioned on two different sides of the area 106, which contains a plurality of pixels PX. The GOP 104 and the PWM-GOP 105 may be fabricated using the same type of thin film transistors, such as HMO transistors, although the disclosure s not limited to this configuration. To achieve improved stability and uniformity for large panels, the main area 106, which includes a plurality of pixels PX, may be implemented using IGZO. It should be noted that FIG. 10 is a schematic representation of the electronic device 10 according to an embodiment of the disclosure, and the actual configuration is not limited to this illustration. The remaining configurations of the electronic device 10 are similar to those of the electronic device 8B and will not be described further.

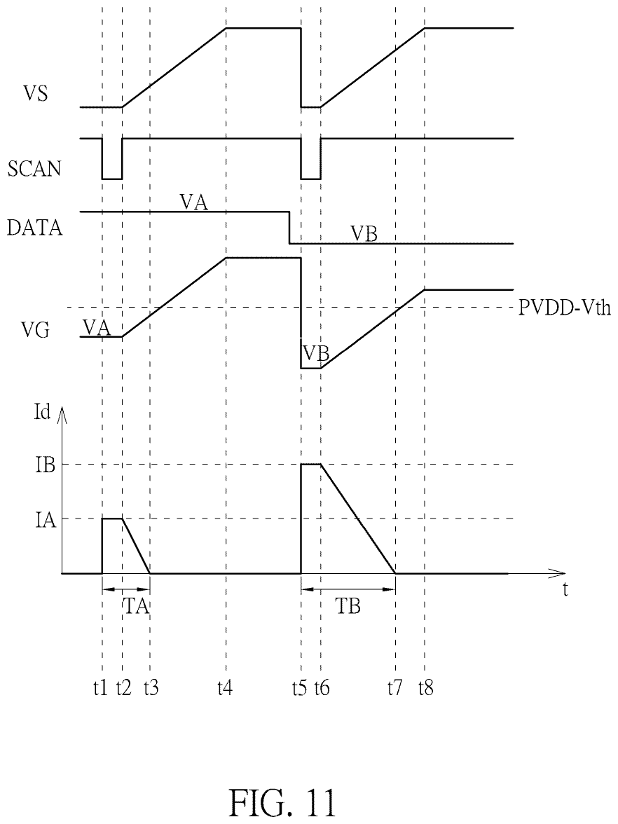

FIG. 11 is a waveform diagram of a circuit of an electronic device 1 according to an embodiment of the disclosure, the horizontal axis is time t, and the vertical axis is voltage or current.

FIG. 11 may be explained with reference to the electronic device 1 depicted in FIG. 1.

At Time t1, the switch signal SCAN switches to logic ‘0’, causing the switching transistor TS to turn on and the sweeping transistor TP to turn off. The data signal DATA on the data line DL is at voltage VA. This voltage VA is transmitted to the first control terminal GL3 of the driving transistor TD via the switching transistor TS, setting the gate voltage VG to VA. Consequently, the current Id is set to a maximum value IA.

At Time t2, the switch signal SCAN switches to logic ‘1’, causing the switching transistor TS to turn off and the sweeping transistor TP to turn on. The sweep signal VS begins to rise from a minimum value (e.g., 0V). The sweep signal VS is transmitted to the first terminal EC1 of the capacitor CP through the sweeping transistor TP, causing the gate voltage VG to rise from VA and the current Id to decrease from the maximum current value IA.

From Time t2 to Time t3, the sweep signal VS continues to rise, causing the gate voltage VG to increase from VA to PVDD-Vth, where PVDD is the supply voltage and Vth is the threshold voltage of the driving transistor. During this period, the current Id decreases from the maximum current value IA to 0 A. In the interval TA, between t1 and t3, the current Id drives the electronic unit 12 to emit light. The magnitude of the current Id during TA is determined by the maximum current value IA, and the duration of TA is determined by the sweep signal VS and the voltage VA.

At Time t3, the gate voltage VG reaches PVDD-Vth. At this point, the driving transistor TD is instantly turned off, and the current Id drops to 0 A.

From Time t3 to Time t4, the sweep signal VS continues to rise to the maximum value, causing the gate voltage VG to increase further. Since VG has exceeded PVDD-Vth, the current Id remains at 0 A.

From Time t4 to Time t5, the sweep signal VS is maintained at the maximum value, keeping the gate voltage VG above PVDD-Vth, and the current Id remains at 0 A. During Time t4 to Time t5, the data signal DATA on the data line DL transitions from VA to VB.

The interval between Time t1 and Time t5 forms the first light-emitting period. The driving transistor TD controls the brightness of the electronic unit 12 during the first light-emitting period, with the maximum current value IA and the time interval TA determining the light emission characteristics.

At Time t5, the switch signal SCAN switches to logic ‘0’, causing the switching transistor TS to turn on and the sweeping transistor TP to turn off. The data signal DATA on the data line DL is at voltage VB. This voltage VB is transmitted to the first control terminal GL3 of the driving transistor TD via the switching transistor TS, setting the gate voltage VG to VB. Consequently, the current Id is set to a maximum current value IB. The voltage VB may be smaller than the voltage VA.

At Time t6, the switch signal SCAN switches to logic ‘1’, causing the switching transistor TS to turn off and the sweeping transistor TP to turn on. The sweep signal VS starts rising from the minimum value (e.g., 0V). The sweep signal VS is transmitted to the first terminal EC1 of the capacitor CP through the sweeping transistor TP, causing the gate voltage VG to increase from VB and the current Id to decrease from the maximum current value IB. The maximum current value IB may be greater than IA.

From Time t6 to Time t7, the sweep signal VS continues to rise, causing the gate voltage VG of the driving transistor TD to increase from VB to PVDD-Vth (where PVDD is the supply voltage and Vth is the threshold voltage). During this period, the current Id decreases from the maximum current value IB to 0 A. In the interval TB between t5 and t7, the current Id drives the electronic unit 12 to emit light. The magnitude of Id during TB is determined by the maximum current value IB, and the duration of TB is influenced by the sweep signal VS and the voltage VB.

At Time t7, the gate voltage VG reaches PVDD-Vth. At this point, the driving transistor TD is instantly turned off, and the current Id drops to 0 A.

From Time t7 to t8, the sweep signal VS continues to rise to the maximum value, causing the gate voltage VG to increase further. Since VG exceeds PVDD-Vth, the current Id remains at 0 A.

Between Time t8 and the next time the switch signal SCAN switches to logic ‘0’, the sweep signal VS is maintained at the maximum value, ensuring that the gate voltage VG stays above PVDD-Vth, and the current Id remains at 0 A.

The interval between t5 and the next time the switch signal SCAN switches to logic ‘0’ forms the second light-emitting period. The driving transistor TD controls the brightness of the electronic unit 12 during the second light-emitting period, with the maximum current value IB and the time interval TB determining the light emission characteristics.

Since the maximum current value IB is greater than the maximum current value IA, the current Id in the second light-emitting period is greater than the current Id in the first light-emitting period. This drives the electronic unit 12 with greater intensity, thereby increasing the brightness of the electronic unit 12. Additionally, since the time interval TB is longer than the time interval TA, the pulse width of the current Id in the second light-emitting period is greater than the pulse width of the current Id in the first light-emitting period. This results in the electronic unit 12 being driven for a longer duration, further increasing the brightness. Therefore, the electronic device circuit 1 is capable of accurately controlling the brightness of the pixel PX through a combination of pulse amplitude modulation (PAM) and pulse width modulation (PWM).

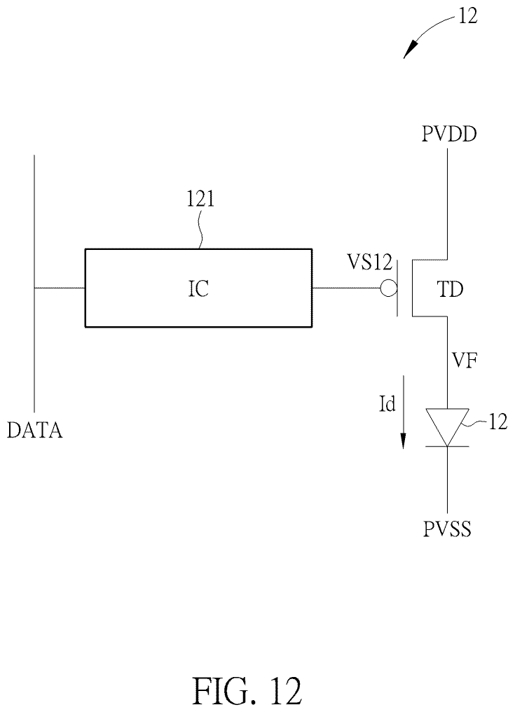

FIG. 12 illustrates a schematic diagram of a circuit for an electronic device 12 according to another embodiment of the disclosure. As shown in FIG. 12, the pulse amplitude modulation (PAM) circuit may be combined with the pulse width modulation (PWM) circuit to form an integrated circuit 121. The driving transistor TD of the PAM circuit 13, as depicted in FIG. 1, is controlled via the sweep signal VS12.

The electronic device described in this disclosure utilizes different channel width-to-length ratios for the driving transistor and the sweeping transistor to enhance the display performance of low-grayscale pixels. Furthermore, by sharing sweep signals between the PWM circuits and PAM circuits, the number of thin film transistors can be reduced, thereby saving space and addressing the issue of overcrowding, ultimately improving resolution.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
an electronic unit;
an integrated circuit configured to provide a sweep signal;
a first transistor comprising a first semiconductor, a first terminal, a second terminal and a first control terminal, wherein the first terminal is electrically connected to a power source, and the second terminal is electrically connected to the electronic unit; and
a second transistor comprising a second semiconductor, a third terminal, a fourth terminal and a second control terminal, wherein the third terminal is configured to receive the sweep signal, the fourth terminal is electrically connected to the first control terminal of the first transistor, and the second control terminal is configured to receive a switch signal;
wherein the first transistor has a first channel width-to-length ratio, the second transistor has a channel width-to-length ratio, and a ratio of the first channel width-to-length ratio to the second channel width-to-length ratio is greater than or equal to 0.03 and less than or equal to 80.5.

2. The electronic device of claim 1, wherein at least one of the first semiconductor and the second semiconductor is an oxide semiconductor.

3. The electronic device of claim 2, wherein the ratio of the first channel width-to-length ratio to the second channel width-to-length ratio is greater than or equal to 0.05 and less than or equal to 57.5.

4. The electronic device of claim 2, wherein both the first semiconductor and the second semiconductor are oxide semiconductors.

5. The electronic device of claim 4, wherein the ratio of the first channel width-to-length ratio to the second channel width-to-length ratio is greater than or equal to 0.2 and less than or equal to 17.3.

6. The electronic device of claim 1, wherein the first transistor has a first channel length, the second transistor has a second channel length, and the first channel length is greater than the second channel length.

7. The electronic device of claim 6, wherein a ratio of the first channel length to the second channel length is greater than or equal to 1.05 and less than or equal to 3.5.

8. The electronic device of claim 7, wherein the ratio of the first channel length to the second channel length is greater than or equal to 1.1 and less than or equal to 2.2.

9. The electronic device of claim 1, further comprising a metal oxide element overlapping the first semiconductor, wherein the first semiconductor is an oxide semiconductor and disposed between the first control terminal and the metal oxide element.

10. The electronic device of claim 9, wherein in a top view of the electronic device, the metal oxide element is greater than the first semiconductor in width.

11. The electronic device of claim 9, further comprising a light shielding element overlapping the first semiconductor, wherein the metal oxide element is disposed between the first semiconductor and the light shielding element.

12. The electronic device of claim 11, wherein the light shielding element directly contacts the metal oxide element.

13. The electronic device of claim 11, wherein the light shielding element is greater than the metal oxide element in width.

14. The electronic device of claim 9, wherein the first semiconductor comprises two openings, and the first control terminal is disposed between the two openings in a top view of the electronic device.

15. The electronic device of claim 1, further comprising:
a first metal oxide element overlapping the first semiconductor; and
a second metal oxide element overlapping the second semiconductor;
wherein the first metal oxide element has a first area, the second metal oxide element has a second area, and a ratio of the first area to the second area is greater than or equal to 1.1 and less than or equal to 10.2.

16. The electronic device of claim 1, wherein the first control terminal and the first semiconductor overlap in a first region, the second control terminal and the second semiconductor overlap in a second region, the first region has a third area, the second region has a fourth area, and a ratio of the third area to the fourth area is greater than or equal to 1.2 and less than or equal to 7.6.

17. The electronic device of claim 1, further comprising a third transistor having a third control terminal electrically connected to the first control terminal, wherein the first transistor is different from the third transistor in channel length.

18. The electronic device of claim 1, wherein the electronic unit is a diode.

19. The electronic device of claim 1, wherein the electronic device has a first portion and a second portion, the first portion surrounds the second portion, and the first transistor and the integrated circuit are both in the second portion.

20. The electronic device of claim 1, wherein the electronic device has a first portion and a second portion, the first portion surrounds the second portion, the first transistor is in the second portion and the integrated circuit is in the first portion.
